(19) United States
(12) Patent Application Publication
(10) Pub. No.: US 2012/0005547 A1
(43) Pub. Date: Jan. 5, 2012

(54) SCALABLE SYSTEM DEBUGGER FOR PROTOTYPE DEBUGGING

(76) Inventors: Chioumin M. Chang, San Jose, CA (US); Thomas B. Huang, San Jose, CA (US); Huan-Chih Tsai, San Jose, CA (US); Ting-Mao Chang, Hsinchu City (TW)

(21) Appl. No.: 12/827,917

(22) Filed: Jun. 30, 2010

(51) Int. Cl. G01R 31/3177; G06F 11/25

(52) U.S. Cl. 714/734; 714/E11.155; 714/724

(57) ABSTRACT

A prototype debugging system controlled by a host processor over a host bus includes: (a) a vector processor interface bus; (b) one or more programmable logic circuits, at least one of which provided to implement: (i) a logic circuit under verification; (ii) one or more programmable embedded debug circuits each receiving a first group of selected signals from the logic circuit under verification and providing control signals for (1) selecting a portion of the first group of selected signals, or (2) affecting the values of a second group of selected signals in the logic circuit under verification based on a portion of the first group of selected signals satisfying a predetermined triggering condition, wherein the programmable embedded debug circuits each including a built-in memory for storing signal vectors, the programmable embedded debug circuits each being configured according to a trigger specification defining one or more trigger states and triggering conditions; and (iii) a local debugging controller that controls programmable embedded debug circuits and transfers signal vectors between the built-in memories of the programmable embedded debug circuits and the vector processor interface bus; and (c) a vector processor which controls transferring of signal vectors between the host processor and the vector processor interface bus.

### BACKGROUND OF THE INVENTION

1. Field of the Invention

The present invention relates to the design and prototyping of electronic circuits. In particular, the present invention relates to verification of a design of an electronic circuit using a programmable logic circuit-based prototyping system.

2. Description of the Related Art

Many advances have been made in prototyping systems for electronic circuits, especially for designs based on a system-on-a-chip (“SOC”) design methodology. Such a system is described, for example, in U.S. patent application publication, 2009/0150838, entitled “Method of Progressively Prototyping and Validating a Customer's Electronic System Design,” Ser. No. 11/953,366, filed on Dec. 10, 2007. Another example is described in U.S. patent application publication, 2009/0150839, entitled “Integrated Prototyping System For Validating An Electronic System Design,” Ser. No. 12/110,233, filed on Apr. 25, 2008. The disclosures of these patent application publications (“Previous Applications”) are hereby incorporated by reference in their entireties.

In these prototyping systems, the design of an electronic circuit is verified in a test system that includes a control processor (sometimes called a “vector processor”, so called because the control processor handles the values of groups of signals, generally known as “signal vectors”) and a number of programmable integrated logic circuits, such as field programmable gate arrays (“FPGAs”). The prototyping system is typically associated with an engineering workstation (“host processor”) having a tool set which includes such tools as a logic simulator and a test bench. With such a tool set, the prototyping system can provide co-simulation or co-emulation capabilities, as is known to those skilled in the art. Typically, the electronic circuit to be verified (“design under verification” or “DUV”) is expressed in a register-transfer-level (RTL) netlist using a conventional hardware description language (e.g., Verilog). A set of automated tools in the workstation transform or synthesize the netlist into logic circuits that can be implemented in the FPGAs. For example, the automated tools partition and synthesize the netlist of the electronic design into partitions of logic circuits based on the resource constraints of the FPGAs, placing and routing the logic circuits in each partition, and configuring each partition into one of the FPGAs. Typically, the prototyping system also configures additional circuitry, such as an embedded vector processor interface (“EVPI”) into each FPGA. The EVPI provides an interface between the partition and other partitions of the electronic design, and between the partition and the vector processor.

In a verification or validation procedure, the workstation provides test vectors and control signals to the prototyping system over a proprietary or an industry standard bus between the prototyping system and a host processor in the workstation. The vector processor provides the test signal vectors (“test vectors”) to the relevant partitions and returns responses (“trace vectors”) from the partitions to the host processor. Various techniques related to such a prototyping system are disclosed, for example, in a copending U.S. patent application (“Copending Application”), Ser. No. 12/476,012, entitled “Method and Apparatus for Verifying Logic Circuits Using Vector Emulation with Vector Substitution,” filed on Jun. 1, 2009. The disclosure of the Copending Application is hereby incorporated by reference in its entirety.

Advances in both density and sophistication of commercially available FPGAs have made it economical and desirable to configure additional test resources in FPGAs in the prototyping system. An embedded logic analyzer (ELA) has been suggested as such an additional resource for testing. The benefits of configuring an ELA in an FPGA along with an assigned partition of the DUV are believed to outweigh the space and complexity overhead costs of the ELA. The ELA is a desirable test resource because it increases visibility of the internal signals of the DUV. As external pins have become a limiting factor in the utilization rate of FPGAs in such a prototyping system, unlike using an external logic analyzer, the ELA allows examining internal signals without requiring the internal signals to be first routed to the accessible output pins of the FPGA. Using an ELA also reduces the number of required iterations of synthesis, place and route, and configuration of the FPGA for viewing different or additional groups of internal signals.

In designing conventional ELAs for a prototyping system, there are a number of constraints, such as: (a) the number of ELAs that can be used in an FPGA, (b) the number of trigger channels which can be used to control how and when trace channels are captured into the built-in memory of an ELA; and (c) the number of trace channels that can be observed and saved into built-in memory by an ELA. It is also desirable to allow the ELA to control the operations of the DUV. As the ELA can only be provided a limited amount of built-in memory, there is a trade-off between the number of traced channels to observe and the number of test vectors that can be saved into built-in memory.

In the prior art, when a user selects a new set of trigger channels or a new set of trace channels, a new iteration of place-and-route, or synthesis and place-and-route operations on the electronic design is required. In many cases, each iteration of such operations may introduce new timing problems. In a conventional design, only one ELA is viewed at a time, and concurrent cross-triggering capability among ELAs is not available.

### SUMMARY

The present invention provides a scalable system debugger (SDD) which may be used in a prototyping system for a DUV, without regard to the number of FPGAs required to implement the DUV (i.e., the SSD “scales up” with the DUV). The SSD may include a vector debugger capability for the integrated prototyping system.

According to one embodiment of the present invention, a prototype debugging system controlled by a host processor over a host bus includes: (a) a vector processor interface bus; (b) one or more programmable logic circuits, at least one of which provided to implement: (i) a logic circuit under verification; (ii) one or more programmable embedded debug circuits each receiving a first group of selected signals from the logic circuit under verification and providing control signals for (1) selecting a portion of the first group of selected signals, or (2) affecting the values of a second group of selected signals in the logic circuit under verification based on a portion of the first group of selected signals satisfying a predetermined triggering condition, wherein the programmable embedded debug circuits each including a built-in memory for storing signal vectors, the programmable embedded debug circuits each being configured according to a trigger specification defining one or more trigger states and triggering conditions; and (iii) a local debugging controller that controls the programmable embedded debug circuits transfers signal vectors between the built-in memories of the programmable embedded debug circuits and the vector processor interface bus; and (c) a vector processor which controls transferring of signal vectors between the host processor and the vector processor interface bus.

In one embodiment, the trigger specification (a) defines trigger states, (b) sets up one or more triggering conditions for each trigger state, and (c) for each triggering condition, specifies the next trigger state and one or more actions to be taken, when the triggering conditions are satisfied.

In one embodiment, the vector processor may include an overall debugging controller that allows a triggering condition defined for a programmable embedded debug circuit in a first programmable logic circuit to affect a triggering condition defined for another programmable embedded debug circuit in the first or a second programmable logic circuit.

In one embodiment, multiplexers controlled by control signals generated by a programmable embedded debug circuit are provided to dynamically select a portion of a first group of selected signals to be received into the programmable embedded debug circuit.

In one embodiment, the logic circuit under verification is modified to include multiplexers controlled by the control signals, the multiplexers forcing or releasing predetermined data values into the second group of selected signals.

In one embodiment, wherein signal vectors are received from the host processor to be stored into programmable embedded debug circuits, and wherein the stored signal vectors may be subsequently injected as values for the second group of selected signals when a DUV is running under in-circuit mode.

In one embodiment, signal vectors are captured upon satisfaction of a triggering condition from a portion of the first group of selected signals.

According to one embodiment of the present invention, an SSD allows a user to modify the operations of a DUV running in in-circuit mode without re-synthesis of the DUV, by allowing forcing and releasing under user control one or more internal signals to pre-determined values, sequences of qualified pre-determined values, or conditioned values.

According to another embodiment of the present invention, an SSD allows a user to increase the number of programmable embedded debug circuit (PEDC) input channels dynamically, using the selector channels at the output of the PEDC to multiplex the PEDC input channels, with a minimum impact on the available resources. In some embodiments, the input PEDC channels include (a) trace channels, which route the internal signals from the DUV for observation, (b) pattern channels, range channels, or trace/release qualifier channels, which control the timing for staring signal vectors of selected trace channel in the built-in memories of PEDC, and (c) a clock channel. In this manner, the SSD allows a user to control the DUV, in addition to the conventional ability of observing internal signals of the DUV. By dynamically selecting input channels, the SSD provides greater controllability and observability of internal signals of a logic circuit is achieved over conventional ELAs. In some embodiments of the output PEDC channels control forcing/releasing predetermined data signals to specified signals in the DUV, or selecting input signals through selector channels.

According to another embodiment of the present invention, an SSD allows cross-triggering among multiple PEDCs, so that synchronized traced vectors may be stored into the respective built-in memory of PEDCs. Such a concurrently cross-triggering capability throughout the entire prototype provides a significant advantage over conventional sequential cross-triggering in the ELAs one FPGA at a time.

According to another embodiment of the present invention, an automated flow is provided to compile a user's design with an SSD.

According to another embodiment of the present invention, the SSD provides a complete in-circuit debugging method.

In one embodiment, a PEDC is implemented as an “embedded micro machine (EMM).”

The PEDC of the present invention requires less FPGA resources than conventional ELAs.

The present invention is better understood upon consideration of the detailed description below in conjunction with the accompanying drawings.

### BRIEF DESCRIPTION OF THE DRAWINGS

FIG. 1 shows an integrated prototyping system (IPS) 100, in accordance with one embodiment of the present invention.

FIG. 2 is a block diagram illustrating the input signals and the output signals of exemplary EMM 200, in accordance with one embodiment of the present invention.

FIG. 3 illustrates the forcing and releasing internal signal 301 of a DUV using the controls signals 304 of force/release channels 207 of an EMM 200, in accordance with one embodiment of the present invention.

FIG. 4 illustrates using the selector signals of selector channel 208 of EMM 200 to select different sets of monitored or observed signals into pattern channels 202, range channels 203, qualifier channels 204, trace channels 205 and force/release qualifier channels 206, in accordance with one embodiment of the present invention.

FIG. 5 provides flow chart 500 which illustrates an automated process of configuring a DUV with an SSD for debugging using EMMs, according to one embodiment of the present invention.

FIG. 6 is a symbolic representation of an exemplary EMM interface, in accordance with one embodiment of the present invention.

FIG. 7 is a flow chart illustrating a prototype debugging method in accordance with one embodiment of the present invention.

FIG. 8 is a flow chart illustrating a process for modifying a faulty circuit block discovered during debugging (e.g., step 705), in accordance with one embodiment of the present invention.

FIG. 9 shows configuration instructions dynamically into an EMM, according to one embodiment of the present invention.

FIG. 10 shows sending data from an EMM to host processor 101, in accordance with one embodiment of the present invention.

To allow cross-referencing among the figures, like elements are assigned like reference numerals.

### DETAILED DESCRIPTION OF THE PREFERRED EMBODIMENTS

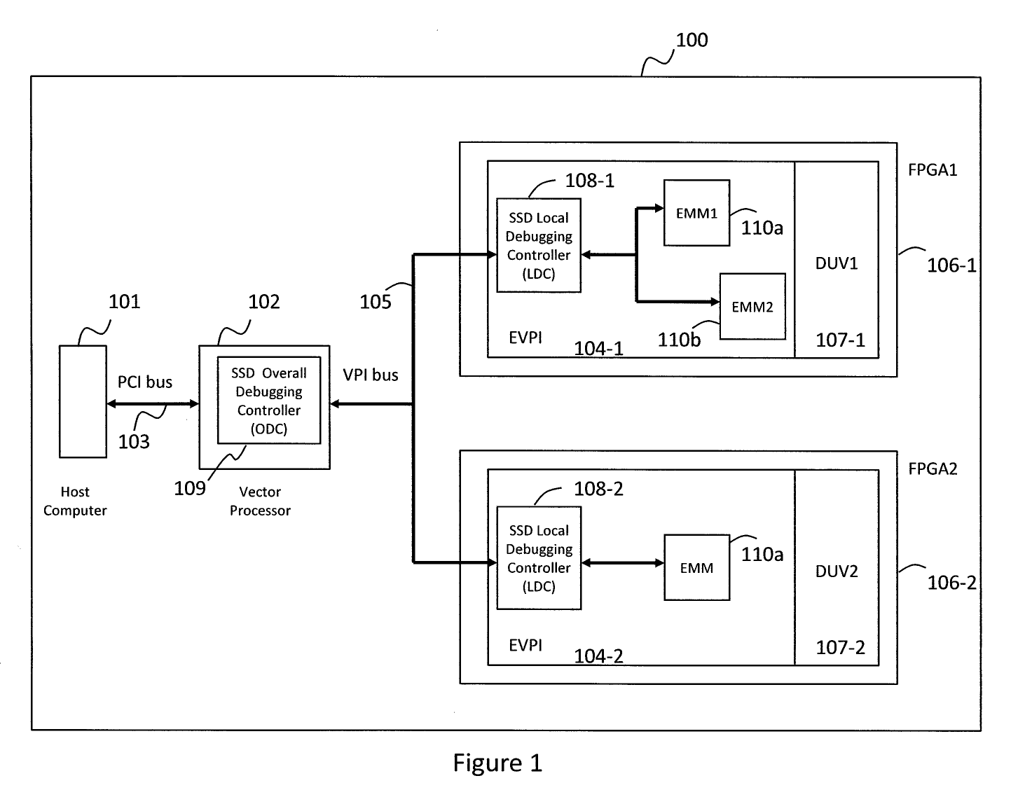

The present invention is applicable to an integrated prototyping system (IPS), such as IPS 100 of FIG. 1. As shown in FIG. 1, IPS 100 includes vector processor 102 which is coupled to host processor 101 over an industry standard PCI bus 103. Vector processor 102 communicates over vector processor interface (VPI) bus 105 with embedded vector processor interfaces (EVPIs) 104-1 and 104-2 implemented in FPGAs 106-1 and 106-2. (Although shown in FIG. 1 with only two FPGAs 106-1 and 106-2, a typical IPS may include any number of FPGAs). EVPI 104-1 and 104-2 provides interfaces between partitions 107-1 and 107-2 of a design under verification (DUV). As shown in FIG. 1 also, one or more EMMs 110-a, . . . 110-n, described in further detail below, may be provided in each EVPI. In this detailed description, the term “EMM” refers to one exemplary implementation of a PEDC. Local debugging controllers (“LDCs”) 108-1 and 108-2 of a scalable system debugger (SSD) are provided in EPVIs 104-1 and 104-2 to control the EMMs configured in the EVPIs. An overall debugging controller (ODC) 109 of SSD is provided in vector processor 102. ODC 109 provides overall control over LDCs 108-1 and 108-2, routing instructions and test vectors from host processor 101 to the LDCs and returns result vectors to host processor 101.

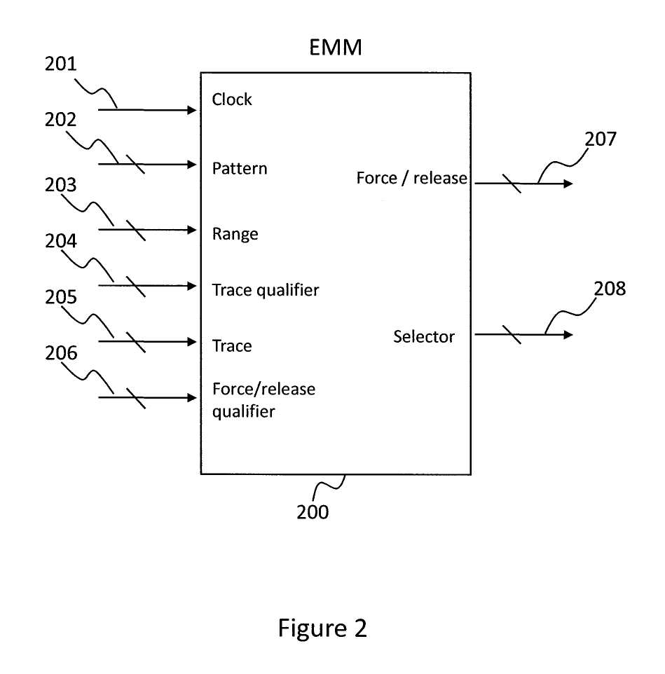

FIG. 2 is a block diagram illustrating the input signals and the output signals of exemplary EMM 200, in accordance with one embodiment of the present invention. As shown in FIG. 2, EMM 200 receives (a) one user design clock signal in clock channel 201; (b) internal signals of the DUV to be observed and saved in trace channels 205; (c) monitored signals from the DUV in pattern channels 202 and range channels 203; (d) qualifier signals from the DUV in trace qualifier channels 204; and (e) monitored signals in force/release qualifier channels 206. EMM 200 provides (a) control signals in force/release channel 207 and (b) selector signals in selector channels 208.

The monitored signals in pattern channels 202 and range channels 203 trigger the beginning time and the ending time of capturing the observed internal signals in trace channels 205. The trace qualifier signals in qualifier channels 204 provide additional filtering to determine whether or not to save the observed internal signals of trace channels 205. The control signals in force/release channel 207 (i) force selected internal signals of the DUV to logic values 0, 1 or a value conditioned by force/release qualifier signals in force/release qualifier channels 206, (ii) invert selected internal signals, (iii) provide pre-determined sequences of logic values; or (iv) release the forced or inverted signals. As described below, the selector signals in selector channels 208 select the signals provided to the input channels 201-206 of EMM 200.

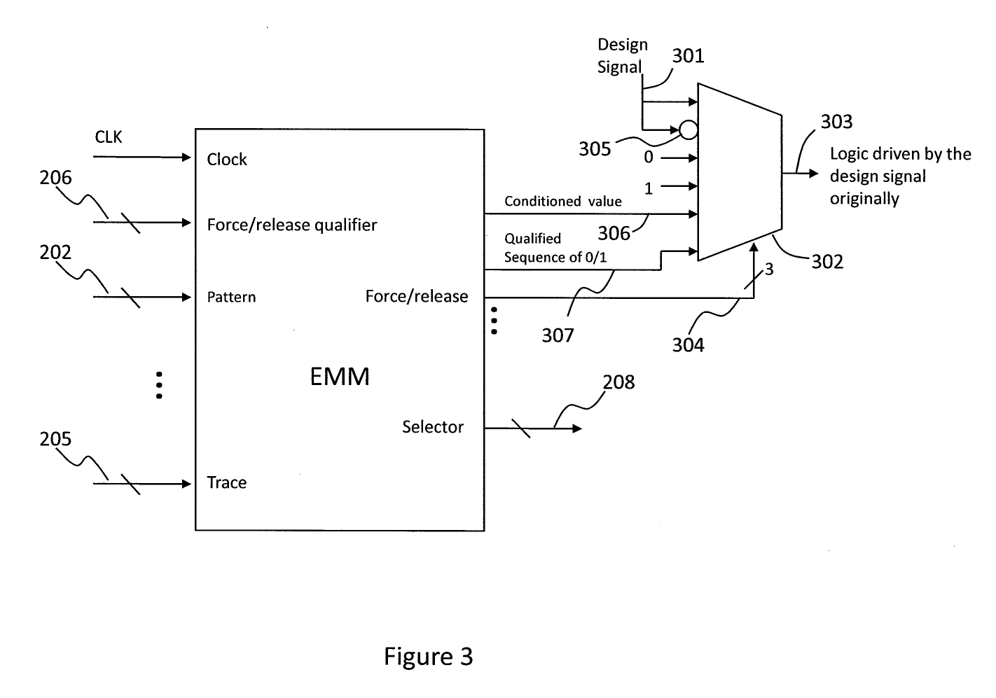

FIG. 3 illustrates the forcing and releasing internal signal 301 of a DUV using the controls signals 304 of force/release channels 207 of an EMM 200, in accordance with one embodiment of the present invention. As shown in FIG. 3, to allow forcing of internal signal 301, multiplexer 302 is inserted in the path of internal signal 301, and output signal 303 of multiplexer 302 is substituted for internal signal 301. Control signals 304 selects as output signal 303 one of the following signals: (a) internal signal 301, (b) inverted form 305 of internal signal 301, (c) logic value ‘0’, (d) logic signal ‘1’, (e) conditioned value 306, and (f) qualified sequence 307 of logic values. Sequence 307 may be obtained from a source such as a built-in memory of an EMM. When it is desired that internal signal 301 be “released,” multiplexer 302 selects internal control signal 301 as its output signal.

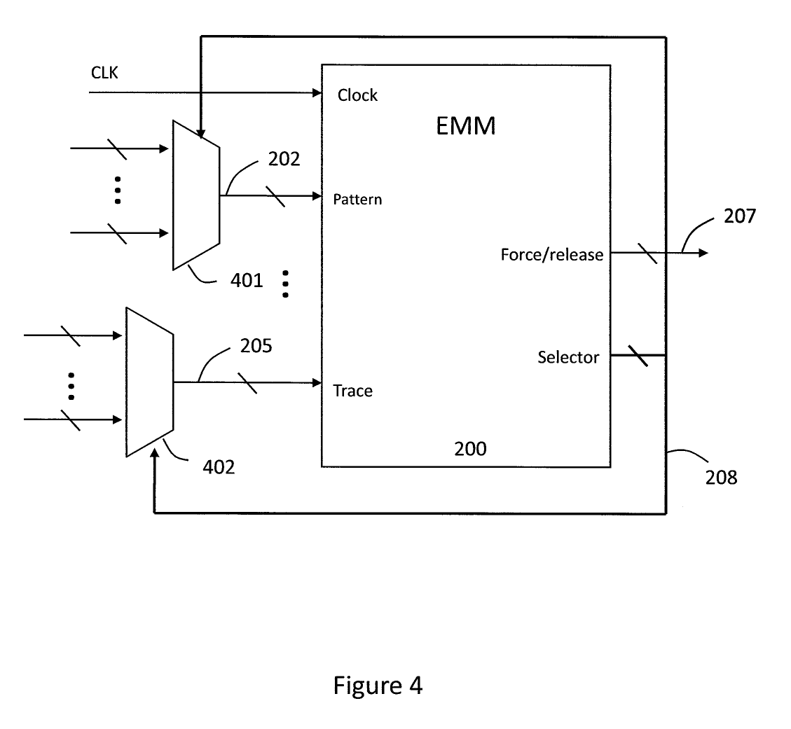

FIG. 4 illustrates using the selector signals of selector channel 208 of EMM 200 to select different sets of monitored or observed signals into pattern channels 202, range channels 203, trace qualifier channels 204, trace channels 205 and force/release qualifier channels 206, in accordance with one embodiment of the present invention. As shown in FIG. 4, multiplexer 401 and 402 are shown as examples of allowing multiple sets of input signals into EMM 200. Specifically, in this example, multiplexer 401 and 402 allow selecting any of multiple sets of monitored signals into pattern channels 202 and selecting any of multiple sets of observed signals into trace channels 205. In this manner, a large number of signals are made available for monitoring or observing during debugging time, even though not all of them are monitored or observed in any given time. These available signals may be selected dynamically when needed during debugging, without requiring an iteration of synthesis and place and route operations on the DUV, as required in the prior art.

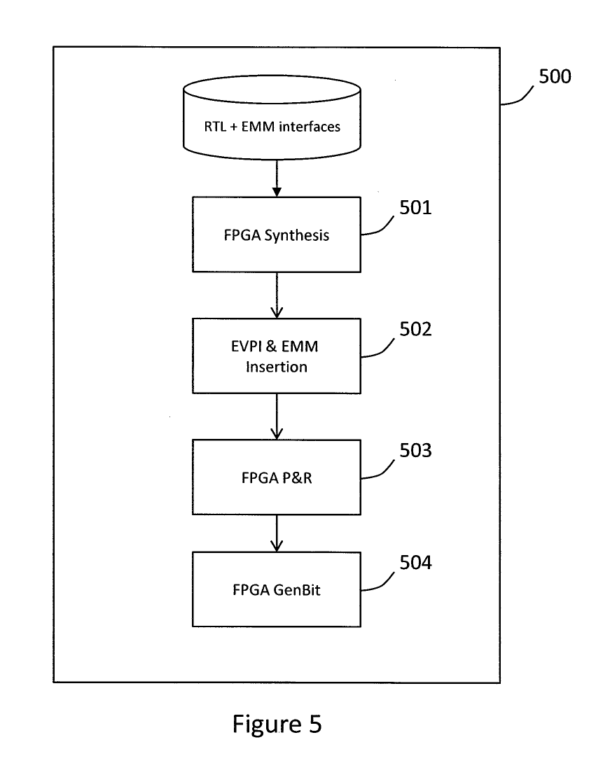

FIG. 5 provides flow chart 500 which illustrates an automated process of configuring a DUV with an SSD for debugging using EMMs, according to one embodiment of the present invention. As shown in FIG. 5, a user first modifies a register-transfer-level (RTL) description of the DUV by inserting into the RTL description “EMM interfaces” (described in further detail below) and selecting internal signals from the DUV to connect to the various channels of each EMM interface. The term “EMM interface” in an RTL description refers to a representation of a circuit object having its external input and output signals defined, but its internal structure is generally not available for examination. At step 501, automated tools partition and synthesize the modified DUV with the EMM interfaces into partitions of logic circuits to be configured into the FPGAs of the prototyping system. At step 502, one or more circuit generation tools of the prototyping system automatically generates and inserts an EVPI for each partition of the DUV, including in each EVPI (a) a LDC and (b) actual circuitry (in place of the EMM interfaces) to implement the specified EMMs, according to an EMM interface specification. The circuit generation tools of step 502 also automatically synthesize the multiplexers associated with the force/release channels 207 and selector channels 208. In addition, the circuit generation tools also provide circuitry for communicating control signals between the LDC 108 and each EMM, and for communicating other required (e.g., signals involved in cross triggering) between the LDC 108 and each EMM.

At step 503, the synthesized logic circuits of the DUV and the circuit generated at step 502 are placed and routed. At step 504, an automated tool generates a bit file from the placed and routed circuit for each FPGA, which can be downloaded into the prototyping system to configure the FPGAs. Prior to debugging, the user defines the initial trigger specification for the EMMs. During debugging, there may be a need to change the trigger specification. If such a change does not involve adding monitored or observed internal signals of the DUV that are not previously associated with the EMM interfaces, the change can be carried out without an iteration of steps 501 through 504. Because no iteration of these steps is required for such a change, significant time is saved for the overall debugging process.

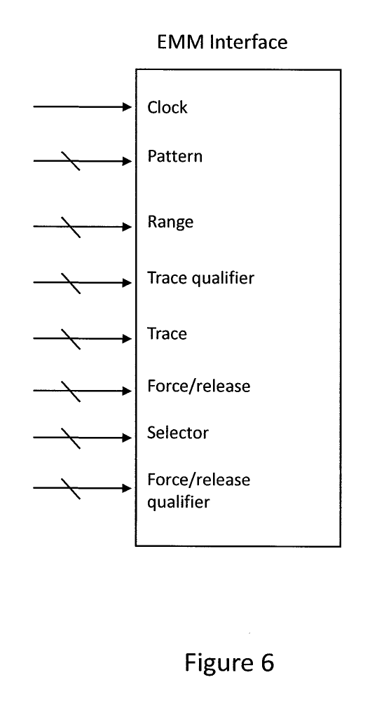

FIG. 6 shows a symbolic representation of an exemplary EMM interface, in accordance with one embodiment of the present invention. When a user first modifies the DUV with an EMM interface, the EMM interface is merely a dummy reference without express internal circuitry. The user specifies internal signals from the DUV to be connected to the various channels (e.g., clock channel 201, pattern channels 202, range channels 203, trace qualifier channels 204, trace channels 205, force/release qualifier channels 206, force/release channels 207), grouping the selected signals into alternative groups so that multiplexers and control signals of selector channels 208 may be synthesized.

According to one embodiment of the present invention, a user defines a trigger specification by specifying each EMM using a machine-readable assertion description language (referred to as the “Prototype Debugging Language”). For each EMM, the trigger specification (a) defines trigger states, (b) sets up one or more triggering conditions for each state, and (c) for each triggering condition, specifies the next trigger state and one or more actions to be taken, when the triggering condition is satisfied. The actions that can be implemented may include (a) saving trace vectors into the built-in memory of the EMM, (b) forcing one or more values or vectors on selected internal signals, (c) releasing one or more selected signals, (d) change values in the selection signals of the selector channels to select one or more different sets of input signals for input channels 201-204 and 206 or trace channels 205, and (e) stopping execution. In addition, the user may specify one or more cross-triggering conditions. A cross-triggering condition is a triggering condition which depends on satisfaction of triggering conditions each from specified different EMMs.

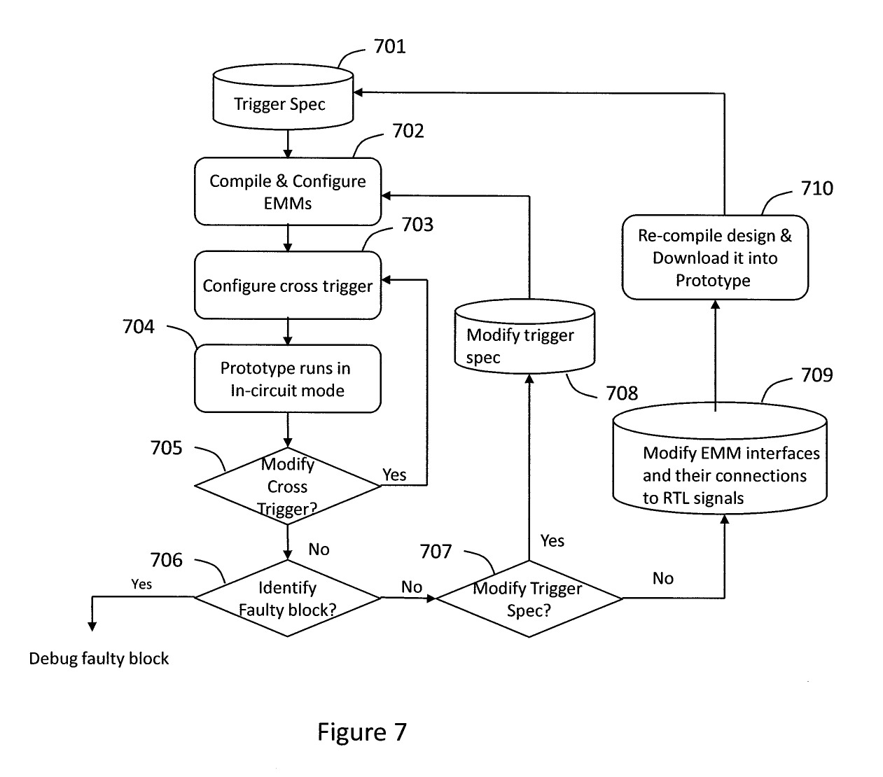

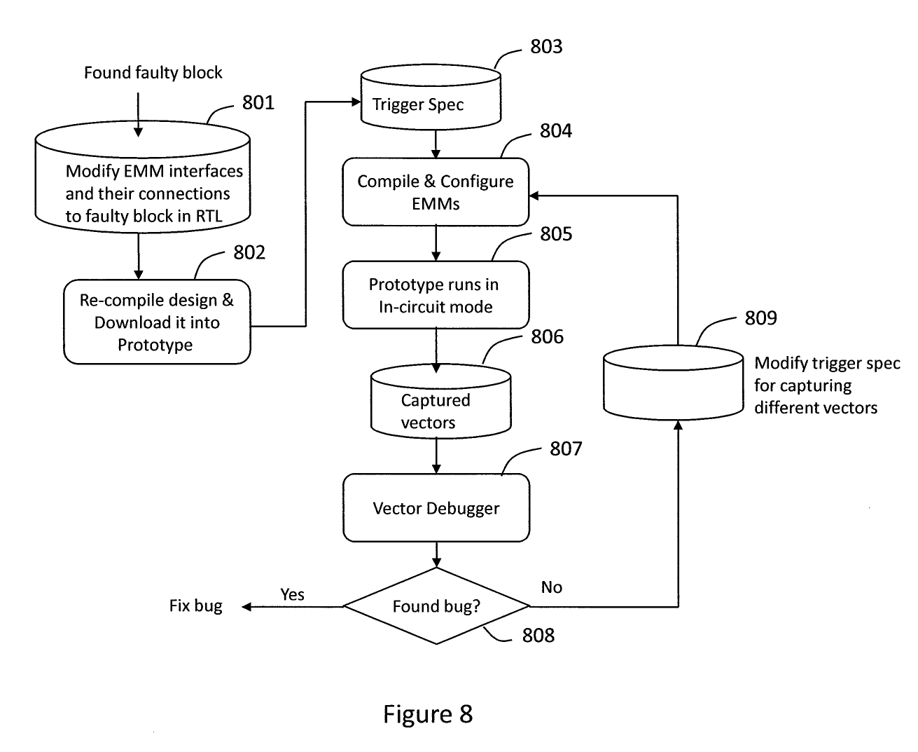

FIG. 7 is a flow chart illustrating a prototype debugging method in accordance with one embodiment of the present invention. As shown in FIG. 7, at step 701, an initial trigger specification is prepared, which is used at step 702 by the trigger configuration tool to compile the trigger specification and configure the EMMs of each EVPI. At step 703, based on the cross-triggering conditions specified in the trigger specification, triggering conditions of EMMs which are involved in cross-triggering are configured among the FPGAs under control by the ODC and LDC over VPI bus 105. At step 704, the prototyping system can then run in “in-circuit” mode for debugging. The results of the in-circuit mode operations may suggest that the user modify the cross-triggering conditions (step 705). If so, the process flow returns to step 703 to reconfigure the cross-triggering conditions. Otherwise, at step 706, the user may examine if a faulty block is identified and which requires the EMMs to be further modified in order to isolate the faulty circuit (“bug”). If so the process illustrated by the flow of FIG. 8 below is followed. Otherwise, i.e., the faulty block has not been identified, the user may consider if a change in the trigger specification without re-specifying one or more EMM interfaces (e.g., additional internal signals should be selected for monitoring or observing) is required (step 707). If so, the user modifies the trigger specification at step 708 and returns to step 702 to implement the changed trigger specification. Alternatively, i.e., the user decides that re-specifying one or more EMM interfaces are required, the EMM interface is re-specified at step 709. The resultant design is recompiled and downloaded into the prototype system at step 710 (e.g., using step 501 through step 504 of FIG. 5, described above) and then returns to step 701 for the prototype debugging.

FIG. 8 is a flow chart illustrating a process for modifying a faulty circuit block discovered during debugging (e.g., step 706), in accordance with one embodiment of the present invention. As shown in FIG. 8, at step 801, one or more EMMs interfaces are modified, including any modifications required that affect the connectivities of the EMM interfaces to the DUV, such as selecting for the EMM interfaces additional internal signals from the identified faulty block to further monitor or observe. Such modifications would help “zoom in” to isolate the faulty circuit. At step 802, the modified RTL description, including the EMM interfaces, is recompiled (e.g., using step 501 through step 504 of FIG. 5, described above). At step 803, a trigger specification is revised according to the modified EMM interfaces. At step 804, the trigger configuration tool compiles the revised trigger specification and configures the modified EMMs of each EVPI. At step 805, the prototyping system 503 is run in “in-circuit” mode under the new configuration. In this embodiment, selected trace vectors are captured during the in-circuit mode (step 806). At step 807, the captured vectors are retrieved into a vector debugger for the user to examine. If the bug is identified, at step 808, a conventional bug-fixing step may follow. Otherwise, the trigger specification may be modified (step 809). The process returns to step 804, based on the modified trigger specification.

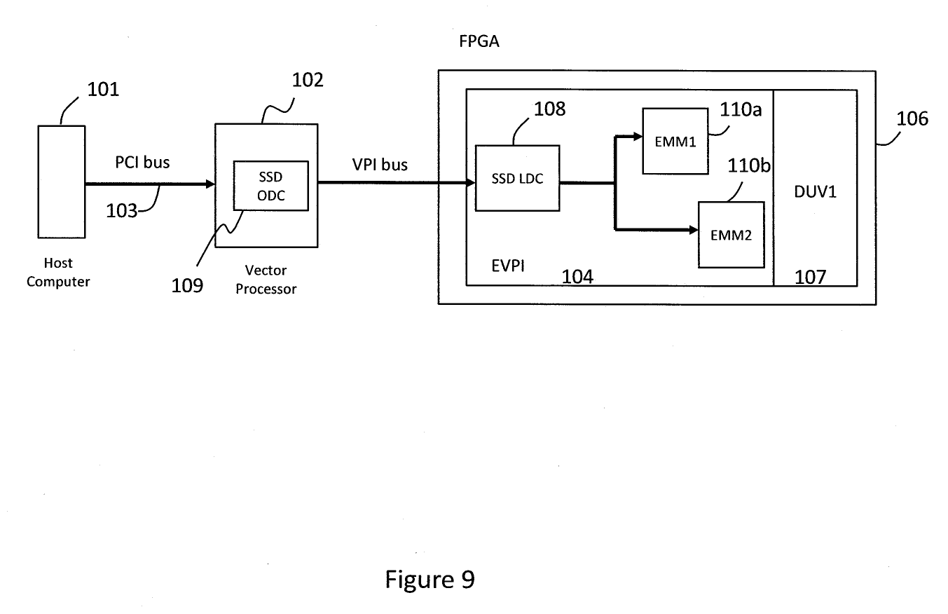

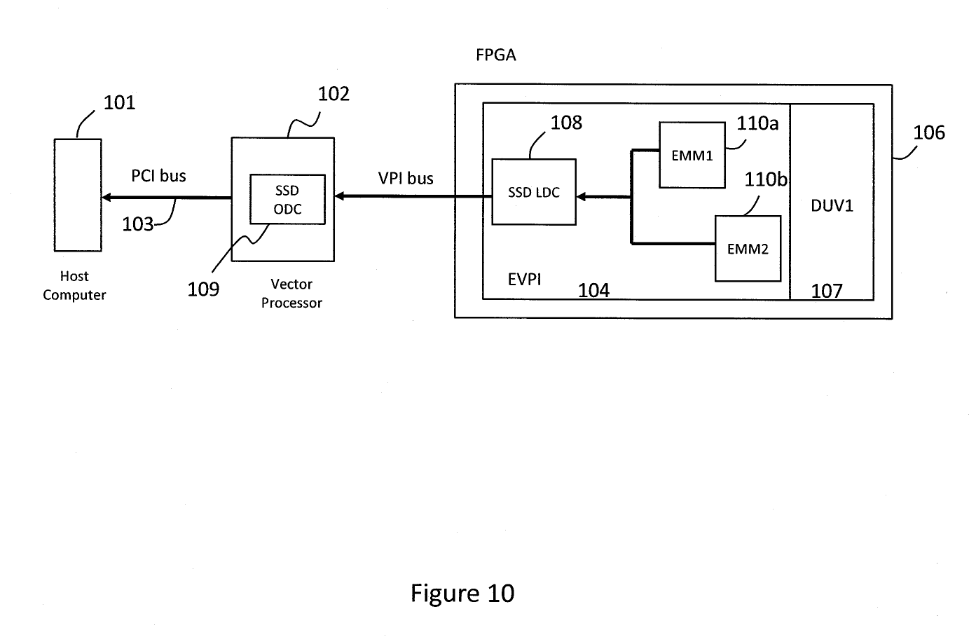

FIG. 9 shows configuration instructions dynamically into an EMM, according to one embodiment of the present invention. Such configuration instructions include, for example, (a) instructions to force a logic value on an internal signal, (b) instructions to download a predetermined data sequence into the built-in memory of an EMM, or (c) defining cross trigger signals between EMMs in different FPGAs. As shown in FIG. 9, configuration instructions are downloaded from host computer 101 over PCI bus 103, which are then received by vector processor 102 (e.g., by operation of SSD ODC 109) and are then provided over VPI bus 105 into EPVI 104. SSD LDC 108 in each EPVI provides the configuration instructions into the appropriate ones of EMM 110-a, . . . , 110-n in the EVPI. Data sent from an EMM to host processor 101 follows generally the reverse direction, as illustrated by FIG. 10. Data sent from an EMM may include, for example, trace vectors captured and stored in the local built-in memory of an EMM.

The detailed description above is provided to illustrate the specific embodiments of the present invention and is not intended to be limiting. Numerous variations and modifications within the scope of the present invention are possible. The present invention is set forth in the accompanying claims.

We claim:

1. A prototype debugging system controlled by a host processor over a host bus, comprises:
a vector processor interface bus;
one or more programmable logic circuits, at least one of which provided to implement:
a logic circuit under verification;
one or more programmable embedded debug circuits each receiving a first group of selected signals from the logic circuit under verification and providing control signals for (a) selecting a portion of the first group of selected signals, or (b) affecting the values of a second group of selected signals in the logic circuit under verification based on a portion of the first group of selected signals satisfying a predetermined triggering condition, wherein the programmable embedded debug circuits each including a built-in memory for storing signal vectors, the programmable embedded debug circuits each being configured according to a trigger specification defining one or more trigger states and triggering conditions; and
a local debugging controller that controls the programmable embedded debug circuits and transfers signal vectors between the built-in memories of the programmable embedded debug circuits and the vector processor interface bus; and
a vector processor which controls transferring of signal vectors between the host processor and the vector processor interface bus.

2. A prototyping system as in claim 1, the vector processor further comprising an overall debugging controller that controls a cross triggering condition defined for multiple programmable embedded debug circuits.

3. A prototyping system as in claim 1, wherein at least one of the programmable embedded debug circuits further comprises multiplexers controlled by control signals generated by the programmable embedded debug circuit to dynamically select a portion of the first group of selected signals to be received into the programmable embedded debug circuit.

4. A prototyping system as in claim 1, wherein the logic circuit under verification is modified to include multiplexers controlled by the control signals, the multiplexers forcing or releasing predetermined data values into the second group of selected signals.

5. A prototyping system as in claim 1, wherein signal vectors are received from the host processor and stored in the programmable embedded debug circuit to be injected as values for the second group of selected signals.

6. A prototyping system as in claim 1, wherein signal vectors are captured upon satisfaction of a triggering condition from a portion of the first group of selected signals.

7. A prototyping system as in claim 1, wherein a portion of the first group of selected signals are used to detect a triggering condition.

8. A prototyping system as in claim 7, wherein a portion of the first group of selected signals provides further qualification to the selected signals traced.

9. A prototyping system as in claim 1, wherein a portion of the first group of selected signals defines a time range for capturing signal vectors.

10. A prototyping system as in claim 1, wherein a portion of the first group of selected signals qualifies how the control signals affect the values of the second group of selected signals.

11. A prototyping system as in claim 1, wherein the prototyping system allows the logic circuit under verification to operate in an in-circuit mode.

12. A prototyping system as in claim 11, wherein the local debugging controller provides run time control and dynamically reconfigures the programmable embedded debug circuits.

13. A prototyping system as in claim 1, wherein the trigger specification (a) defines trigger states, (b) sets up one or more triggering conditions for each trigger state, and (c) for each triggering condition, specifies the next trigger state and one or more actions to be taken, when the triggering conditions are satisfied.

14. A prototyping system as in claim 1, wherein the signal vectors captured into the built-in memory are used by the vector debugger for vector debugging.

15. A programmable embedded debug circuit configured in a programmable logic circuit for debugging a logic circuit under verification configured in the programmable logic circuit, comprising:
Input interfaces for receiving a first group of selected signals from the logic circuit under verification; and
Output interfaces for providing control signals for (a) selecting a portion of the first group of selected signals, or (b) affecting the values of a second group of selected signals in the logic circuit under verification based on a portion of the first group of selected signals satisfying a predetermined triggering condition; and
wherein the programmable embedded debug circuits each include a built-in memory for storing signal vectors, the programmable embedded debug circuits are each configured according to a trigger specification defining one or more trigger states and triggering conditions,

16. A programmable embedded debug circuit as in claim 15, wherein a local debugging controller configured in the programmable logic circuit transfers signal vectors between the built-in memory and the vector processor interface bus.

17. A programmable embedded debug circuit as in claim 15, further comprising multiplexers controlled by control signals generated by the programmable embedded debug circuit to dynamically select a portion of the first group of selected signals to be received into the programmable embedded debug circuit.

18. A programmable embedded debug circuit as in claim 15, wherein the logic circuit under verification is modified to include multiplexers controlled by the control signals, the multiplexers forcing or releasing predetermined data values into the second group of selected signals.

19. A programmable embedded debug circuit as in claim 15, wherein signal vectors are captured upon satisfaction of a triggering condition from a portion of the first group of selected signals.

20. A programmable embedded debug circuit as in claim 15, wherein a portion of the first group of selected signals are used to detect a triggering condition.

21. A programmable embedded debug circuit as in claim 15, wherein a portion of the first group of selected signals provides further qualification to the selected signals traced.

22. A programmable embedded debug circuit as in claim 15, wherein a portion of the first group of selected signals defines a time range for capturing signal vectors.

23. A programmable embedded debug circuit as in claim 15, wherein a portion of the first group of selected signals qualifies how the control signals affect the values of the second group of selected signals.

24. A programmable embedded debug circuit as in claim 15, wherein the prototyping system allows the logic circuit under verification to operate in an in-circuit mode.

25. A programmable embedded debug circuit as in claim 24, wherein the local debugging controller provides run time control and dynamically reconfigures the programmable embedded debug circuits.

26. A programmable embedded debug circuit as in claim 15, wherein the trigger specification (a) defines trigger states, (b) sets up one or more triggering conditions for each trigger state, and (c) for each triggering condition, specifies the next trigger state and one or more actions to be taken, when the triggering conditions are satisfied.

27. A method for debugging a logic circuit under verification in a prototyping system having one or more programmable logic circuits, comprising:
including in a register-transfer-level (RTL) description of the logic circuit under verification (DUV), one or more programmable embedded debug circuits each represented as a programmable embedded debug circuit interface in the RTL description with input interfaces coupled to selected internal signals of the DUV and output interfaces coupled to selected internal signals of the DUV;
synthesizing the DUV from the RTL description for implementation in the programmable logic circuits;
saving the synthesized DUV;
synthesizing an actual debug circuit for each programmable debug circuit using a corresponding trigger specification;
configuring the saved synthesized DUV and the synthesized actual debug circuit into the programmable logic circuits; and
operating the prototyping system in an in-circuit mode with the configured programmable logic circuit.

28. A method as in claim 26, further comprising:
synthesizing a second actual debug circuit for each programmable debug circuit using a second trigger specification and configuring the saved synthesized DUV and the second actual debug circuit into the programmable logic circuit; and
operating the prototyping system in an in-circuit mode with the configured programmable logic circuit.

29. A method as in claim 27, wherein synthesizing the DUV from the RTL description further comprises partitioning the DUV, each partition of the DUV to be configured in the configuring step into one of the programmable logic circuit.

30. A method as in claim 27, further comprising synthesizing a local debugging controller to be configured in the configuring step into each programmable logic circuit to control transferring of signal vectors between a built-in memory in the synthesized actual debug circuit and the vector processor interface bus.

31. A method as in claim 30, wherein the local debugging controller provides run time control and dynamically reconfigures the synthesized actual debug circuits.

32. A method as in claim 27, wherein synthesizing the actual debug circuit further comprises synthesizing multiplexers controlled by the output signals of the synthesized actual debug circuit to dynamically select a portion of the input signals to be received into the actual debug circuit.

33. A method as in claim 27, wherein synthesizing the actual debug circuit further comprises synthesizing multiplexers controlled by the output signals of the synthesized actual debug circuit, the multiplexers forcing or releasing predetermined data values into selected internal signals of the DUV.

34. A method as in claim 27, wherein signal vectors are captured upon satisfaction of a triggering condition from a portion of the input signals.

35. A method as in claim 27, wherein a portion of input signals is used to detect a triggering condition.

36. A method as in claim 35, wherein a portion of input signals provides further qualification to the selected signals traced.

37. A method as in claim 27, wherein a portion of the input signals defines a time range for capturing signal vectors.

38. A method as in claim 27, wherein a portion of the input signals qualifies how the control signals affect the values of selected internal signals.

39. A method as in claim 27, wherein the trigger specification (a) defines trigger states, (b) sets up one or more triggering conditions for each trigger state, and (c) for each triggering condition, specifies the next trigger state and one or more actions to be taken, when the triggering conditions are satisfied.
